(19) United States
(12) Patent Application Publication
(10) Pub. No.: US 2022/0158619 A1
(43) Pub. Date: May 19, 2022

(54) METHOD FOR PRODUCING SEALED FUNCTIONAL ELEMENTS

(71) Applicant: Horst Siedle GmbH & Co. KG, Furtwangen (DE)

(72) Inventors: Ernst HALDER, Stuttgart (DE); Michael ULMER, Eislingen (DE); Tobias ECKERT, Gundelfingen (DE); Kai ZOSCHKE, Berlin (DE)

(73) Assignee: Horst Siedle GmbH & Co. KG, Furtwangen (DE)

(21) Appl. No.: 17/415,787

(22) PCT Filed: Jul. 14, 2020
(86) PCT No.: PCT/EP2020/069882

§ 371 Date: Jun. 18, 2021

(30) Foreign Application Priority Data
Aug. 1, 2019 (DE) 10 2019 120 844.0

(51) Int. Cl. H03H 9/25; H01L 21/67; H03H 3/08

(52) U.S. Cl. CPC H03H 9/25; H03H 3/08; H01L 21/67126

(57) ABSTRACT

A method for manufacturing a plurality of, in particular hermetically, sealed functional elements, comprising the following steps: providing a first wafer comprising the plurality of functional elements, providing a second wafer, applying a sealing material in the form of a plurality of frame structures on a first surface of the second wafer, placing the second wafer on the first wafer or vice versa, joining the first wafer with the second wafer.

The disclosure relates to a method of manufacturing sealed functional elements.

The disclosure further relates to a sealed functional element.

Preferred embodiments relate to a method for manufacturing a plurality of, in particular hermetically, sealed functional elements comprising the following steps: providing a first wafer comprising the plurality of functional elements, providing a second wafer, applying a sealing material in the form of a plurality of frame structures on a first surface of the second wafer, placing the second wafer on the first wafer or vice versa, joining the first wafer with the second wafer. Thus, a variety of sealed functional elements can be efficiently manufactured at wafer level.

Preferably, “hermetically sealed” is here understood to mean gas-tight sealing of the functional elements, in particular gas-tight under normal conditions such as at 23° C. More preferably, the gas-tight seal is provided under conditions of use, i.e. in a temperature range from −40° C. to +125° C. This advantageously ensures in further preferred embodiments that no exchange of substances, in particular particles or solids, and gas (or gases) is possible between an interior of a respective functional element and an environment of the respective functional element. In this way, in particular the interior of the functional element(s) can be kept free of disturbing influences that otherwise possibly cause a malfunction of the functional elements.

In further preferred embodiments, it is provided that some, preferably all, of the functional elements are surface acoustic wave (SAW) functional elements, wherein in particular the functional elements are arranged on a first surface of the first wafer.

A surface acoustic wave, abbreviated with SAW, is a structure-borne sound wave that propagates in a planar manner on a surface. SAW functional elements or SAW sensors utilize the dependence of the surface wave velocity on mechanical stress (deformation) and/or mass application (e.g. deposits on the surface) and/or temperature (temperature coefficient of the sound velocity). The use of SAW sensors may be particularly suitable where, for certain reasons, locations to be measured are hardly accessible.

A particular challenge in the manufacture and use of SAW functional elements or SAW sensors containing one or more SAW functional elements is the protection of the surface of the SAW functional element(s) against contamination.

The principle according to preferred embodiments enables a process-safe and in particular economical manufacture of SAW functional elements and SAW sensors, as well as an efficient protection in particular of the surface of the SAW functional element(s) against contamination during the manufacturing process and subsequent use.

In further preferred embodiments, it is provided that after the placing, at least one frame structure surrounds at least one functional element of the plurality of functional elements. In this way, an interior can be defined which includes the at least one functional element and can be, preferably hermetically, sealed off from the environment by the two wafers and by the frame structure. In other words, in further preferred embodiments, respective regions of the first wafer may form a bottom wall delimitating the interior, respective regions of the second wafer may form a top wall delimitating the interior, and the frame structure may form at least one side wall that can be coupled in a preferably hermetically sealed manner to the bottom wall and the top wall.

In further preferred embodiments, it is provided that after the placing, a plurality of frame structures each surround at least a predeterminable first number of functional elements. Accordingly, this enables one or more functional elements to be surrounded at least laterally by the frame structure(s).

In further preferred embodiments, it is provided that after the placing, a plurality of frame structures each surround exactly a predeterminable second number of functional elements, wherein in particular the second number being less than or equal to four, wherein in particular the second number being exactly one.

Accordingly, in further preferred embodiments, it can be provided that the one or more frame structures are applied onto the second wafer in dependence on an arrangement of the functional elements on the first wafer.

In further preferred embodiments, it is provided that more than 50 percent of the plurality of frame structures each surround exactly the (respective) second number of functional elements, wherein in particular more than 90 percent of the plurality of frame structures each surround exactly the second number of functional elements.

In further preferred embodiments, it is provided that at least some of the frame structures, preferably all of the frame structures, have a height of between 1.0 micrometer (μm) and 30 μm, in particular between 2.5 μm, and 20 μm, further in particular between 5 μm and 15 μm, and preferably about 10 μm. Thus, the interior to be sealed has a sufficient height to accommodate any SAW functional elements or individual SAW structures thereof that may protrude from a surface plane of the first wafer, without these touching the second wafer after joining, for example.

In further preferred embodiments, it is provided that the applying of the sealing material in the form of the plurality of frame structures comprises: applying the plurality of frame structures in a matrix-shaped arrangement having a plurality of rows and a plurality of columns.

In further preferred embodiments, it is provided that the applying of the sealing material in the form of the plurality of frame structures comprises: applying the plurality of frame structures such that at least a first spacing of adjacent frame structures on the first surface of the second wafer, which is viewed in particular along a first coordinate axis, corresponds to a corresponding second spacing of adjacent functional elements on the first wafer, wherein in particular the applying of the sealing material in the form of the plurality of frame structures comprises: applying the plurality of frame structures such that the first spacing of adjacent frame structures on the first surface of the second wafer, which is viewed in particular along the first coordinate axis, corresponds to a corresponding second spacing of adjacent functional elements on the first wafer, and that a third spacing of adjacent frame structures on the first surface of the second wafer, which is viewed in particular along a second coordinate axis perpendicular to the first coordinate axis, corresponds to a corresponding fourth spacing of adjacent functional elements on the first wafer.

In further preferred embodiments, it is provided that at least some of the frame structures, preferably all of the frame structures, have a substantially polygonal basic shape, in particular rectangular shape (or also rounded rectangular shape) or square shape.

In further preferred embodiments, it is provided that the applying of the sealing material is performed using a screen printing method.

In further preferred embodiments, it is provided that a glass solder is used as the sealing material.

In further preferred embodiments, it is provided that the method further comprises: performing a heat treatment on the second wafer on which the sealing material is applied in the form of the plurality of frame structures, wherein in particular the heat treatment has a predeterminable temperature profile.

In further preferred embodiments, it is provided that performing the heat treatment comprises: heating the second wafer during a first (time) period to a predeterminable first temperature, wherein in particular the first period is between 20 minutes and 120 minutes, preferably 60 minutes, wherein in particular the first temperature is between 420 and 690 degrees Celsius, preferably between 520 and 600 degrees Celsius, further preferably about 560 degrees Celsius.

In further preferred embodiments, it is provided that performing the heat treatment comprises: maintaining a predeterminable second temperature for a second period, wherein in particular the predeterminable second temperature corresponds at least approximately to the first temperature, wherein in particular the second period is between 10 minutes and 90 minutes, further in particular between about 20 minutes and about 60 minutes, further preferably about 40 minutes.

In further preferred embodiments, it is provided that performing the heat treatment comprises: cooling, in particular to room temperature, during a third period, wherein in particular the third period is between 6 hours to 24 hours, further in particular between 12 hours and 20 hours, further preferably between 15 hours and 18 hours.

In further preferred embodiments, it is provided that the method further comprises: removing material from the first surface of the second wafer down to a predeterminable first depth that is less than 80 percent of a thickness of the second wafer, in particular less than 60 percent of the thickness of the second wafer.

In further preferred embodiments, it is provided that the removing is performed after performing the heat treatment.

In further preferred embodiments, it is provided that the removing of material is performed between mutually adjacent frame structures.

In further preferred embodiments, it is provided that the removing of material comprises performing saw cuts.

In further preferred embodiments, it is provided that the first depth is between 20 μm and 150 μm, in particular between 20 μm and 100 μm.

In further preferred embodiments, the joining comprises: pressing the first wafer to the second wafer under a predeterminable pressure and/or a predeterminable temperature, wherein the predeterminable pressure is between about 200 Pascal (Pa), and about 12000 Pa, in particular between 500 Pa and 6000 Pa, wherein in particular the predeterminable temperature is between 300 and 700 degrees Celsius.

In further preferred embodiments, it is provided that the pressing is performed for a period of 5 seconds to 10 hours, in particular of 10 seconds to 5 hours.

In further preferred embodiments, it is provided that the method further comprises: removing material from the second surface of the second wafer, in particular by grinding and/or milling, wherein in particular the removing is performed such that a plurality of regions of the second wafer are diced (separated) from each other.

In further preferred embodiments, it is provided that the method further comprises: testing, in particular preferably electrically characterizing, of individual or multiple functional elements, in particular at wafer level.

In further preferred embodiments, it is provided that the method further comprises: dicing (separating) a plurality of the functional elements, in particular by sawing.

In further preferred embodiments, it is provided that the method further comprises: further processing of at least one separated functional element, in particular installing the at least one separated functional element in a target system, e.g. soldering and/or bonding onto a mechanical shaft.

In further preferred embodiments, it is provided that the first wafer and/or the second wafer is a quartz wafer. In further preferred embodiments, it is provided that the first wafer and/or the second wafer comprises at least one of the following materials: lithium niobate (LiNbO₃) and/or lithium tantalate (LiTaO₃). Further preferred embodiments relate to a wafer assembly obtained by the method according to the embodiments, comprising a first wafer having a plurality of functional elements and a second wafer.

Further preferred embodiments relate to a sealed functional element obtained by the method according to the embodiments.

Further preferred embodiments relate to a sealed functional element comprising a first substrate on which the functional element is located, at least one second substrate, and at least one frame structure surrounding the functional element, wherein the first substrate is connected to the second substrate by the frame structure, in particular cohesively connected, wherein an in particular hermetically sealed interior is defined between the first substrate and the second substrate and the frame structure.

Further preferred embodiments relate to a use of at least one sealed functional element according to the embodiments for determining a quantity which characterizes a torque.

Further characteristics, applications and advantages of the invention can be derived from the following description of embodiments of the invention, which are shown in the drawing figures. Here, all the features described or illustrated constitute the subject-matter of the invention, either individually or in any combination, irrespective of their combination in the claims or their correlation, and irrespective of their formulation or representation in the description or in the drawings.

In the drawings:

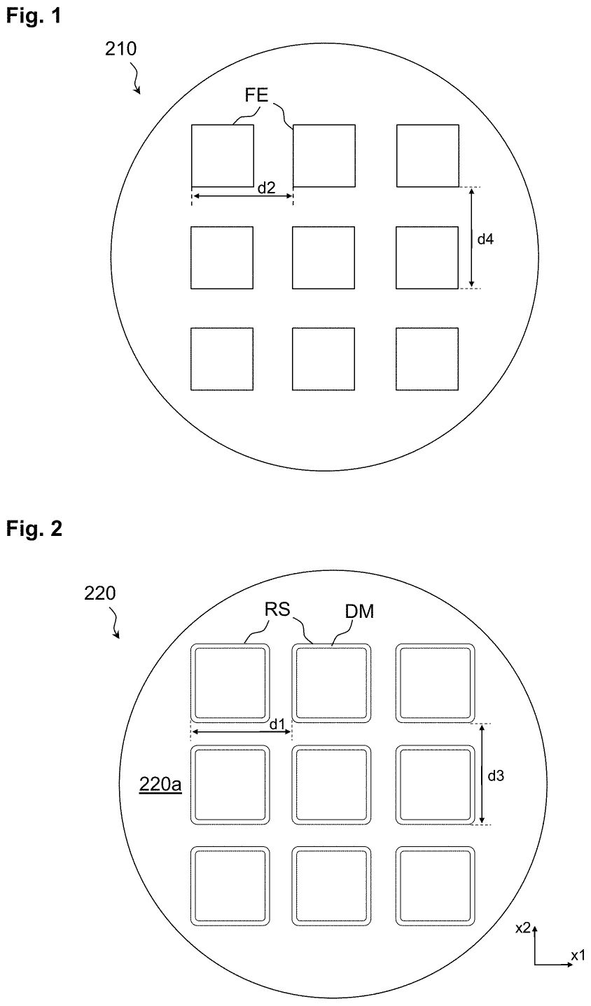

FIG. 1 schematically shows a top view of a first wafer according to preferred embodiments,

FIG. 2 schematically shows a top view of a second wafer according to further preferred embodiments,

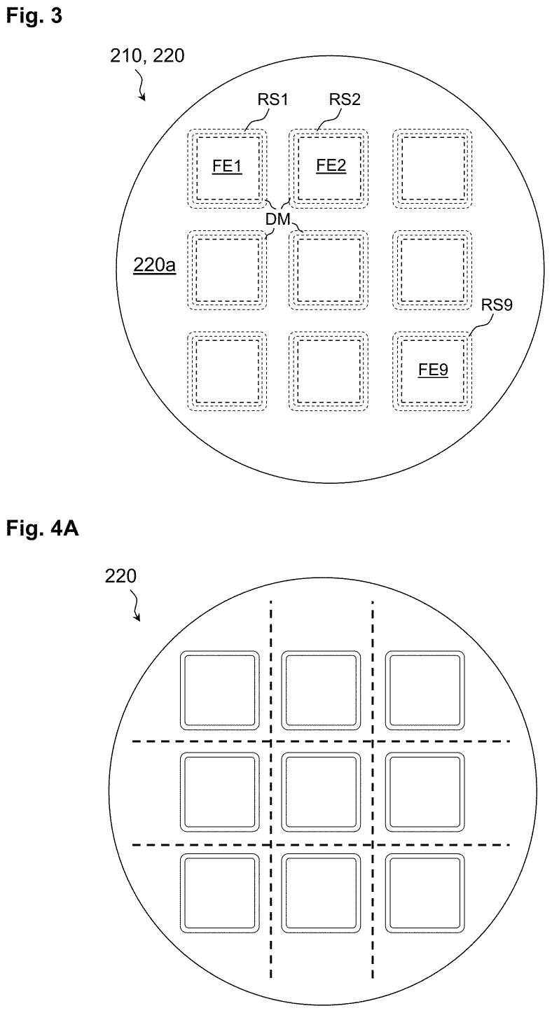

FIG. 3 schematically shows a top view of a virtual superposition of the first wafer according to FIG. 1 and the second wafer according to FIG. 2 according to further preferred embodiments,

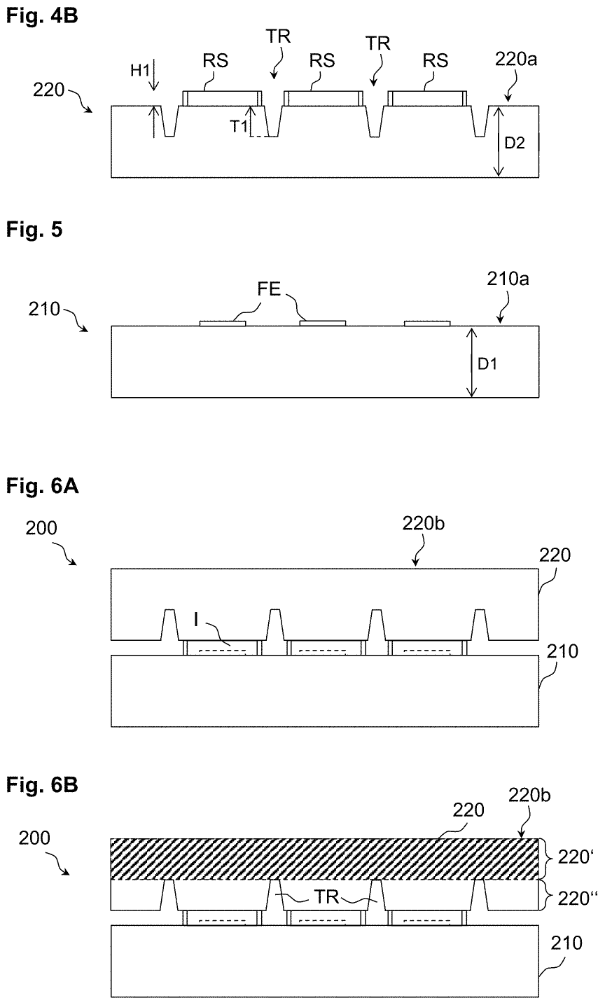

FIG. 4A schematically shows a top view of the second wafer according to further preferred embodiments,

FIG. 4B schematically shows a side view of the second wafer according to further preferred embodiments,

FIG. 5 schematically shows a side view of the first wafer according to further preferred embodiments,

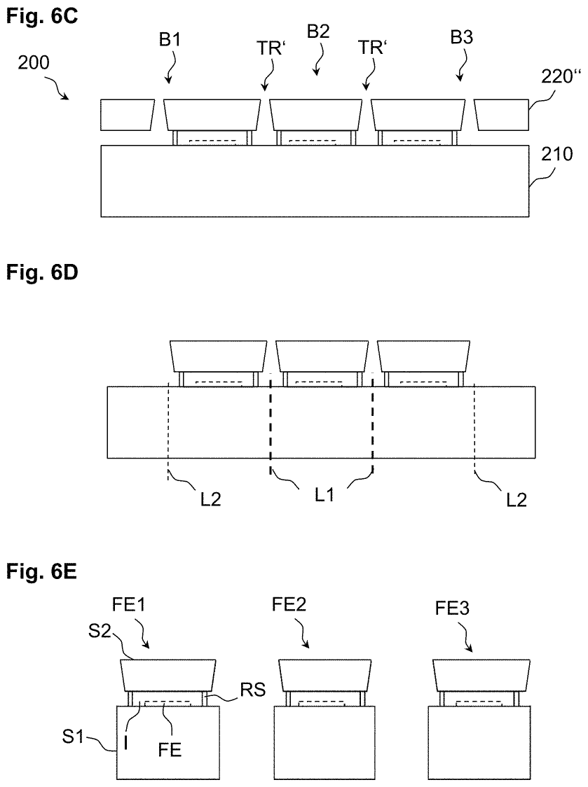

FIG. 6A to 6D each schematically show a respective side view of a wafer assembly according to further preferred embodiments,

FIG. 6E schematically shows diced functional elements according to further preferred embodiments,

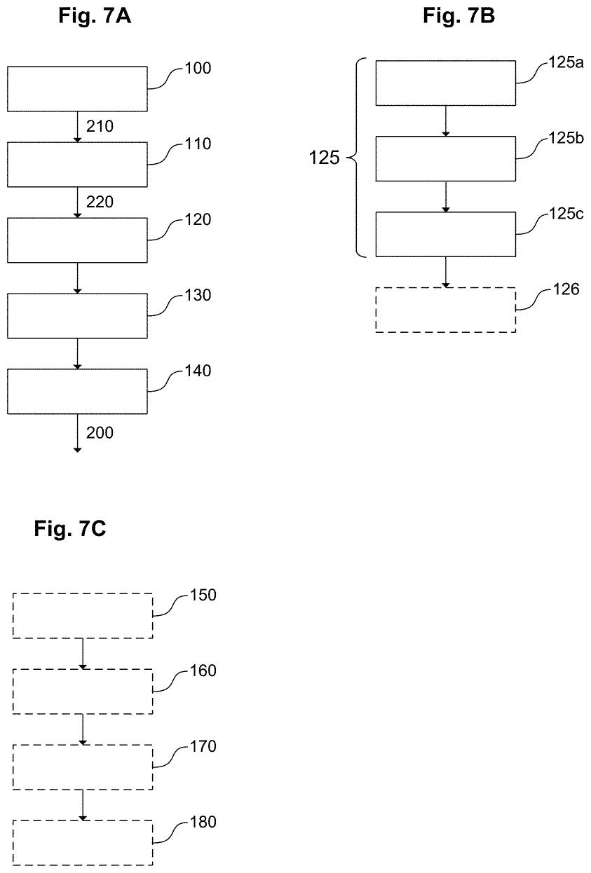

FIG. 7A schematically shows a simplified flowchart of a method according to preferred embodiments,

FIG. 7B schematically shows a simplified flowchart of a method according to further preferred embodiments,

FIG. 7C schematically shows a simplified flowchart of a method according to further preferred embodiments,

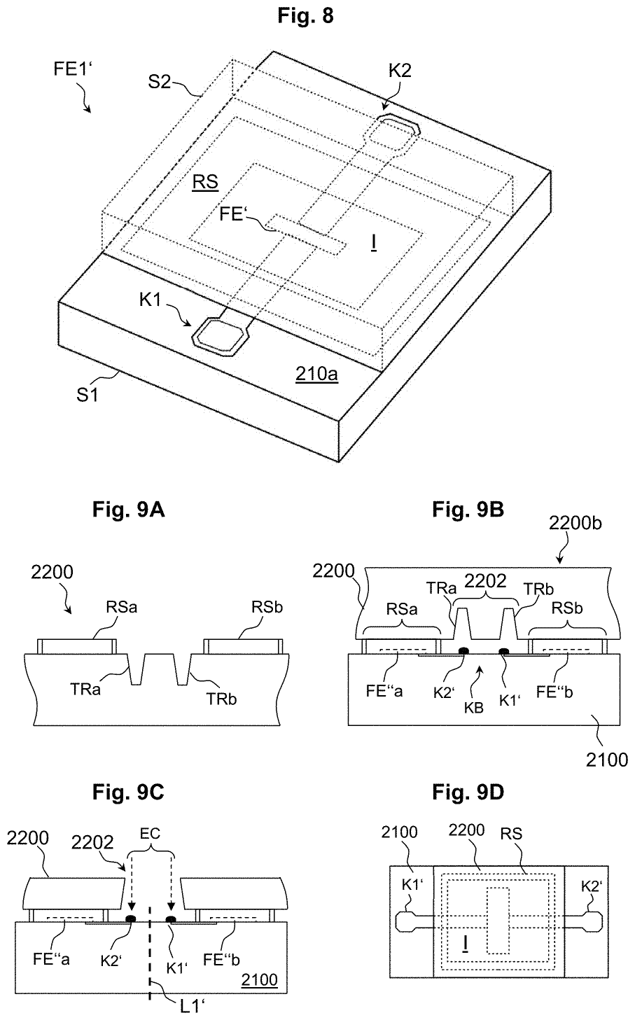

FIG. 8 schematically shows a perspective view of a sealed functional element according to further preferred embodiments,

FIG. 9A to 9C each schematically show a side view according to further preferred embodiments,

FIG. 9D schematically shows a top view of a functional element according to further preferred embodiments,

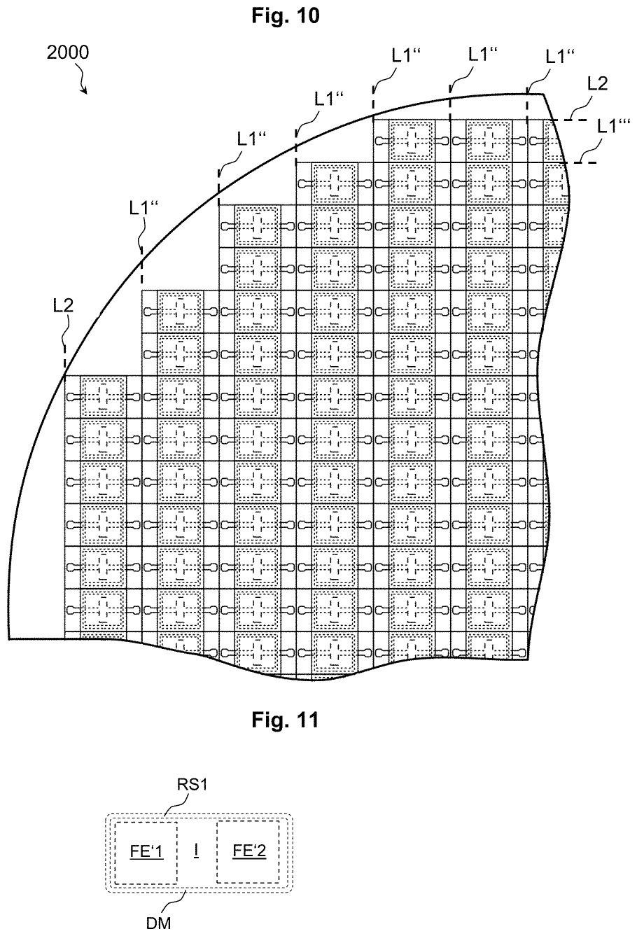

FIG. 10 schematically shows a top view of a wafer assembly according to further preferred embodiments, and

FIG. 11 schematically shows a top view of functional elements of a virtual superposition of a first wafer and a second wafer according to further preferred embodiments.

Preferred embodiments relate to a method for manufacturing a plurality of, in particular hermetically, sealed functional elements FE1, FE2, FE3, cf. FIG. 6E, wherein the method comprises the steps described below by way of example with reference to FIG. 7A: providing 100 a first wafer 210 comprising the plurality of functional elements FE, cf. e.g. the top view of FIG. 1, providing 110 (FIG. 7A) a second wafer 220, cf. also the top view of FIG. 2, applying 120 (FIG. 7A) a sealing material DM (FIG. 2) in the form of a plurality of frame structures RS on a first surface 220a of second wafer 220, placing 130 (FIG. 7A) second wafer 220 on first wafer 210 or vice versa, and joining 140 (FIG. 7A) first wafer 210 with second wafer 220. With the joining 140, preferably a monolithic wafer structure 200 is obtained which comprises first wafer 210 and second wafer 220, cf. e.g. the side view of FIG. 6A. By the method described above by way of example with reference to FIG. 7A, according to preferred embodiments, a plurality of sealed functional elements can be efficiently manufactured at wafer level, thus greatly simplifying handling compared to conventional methods.

In further preferred embodiments, one or more steps of the method described above may also be carried out, if necessary, at least partially overlapping in time or simultaneously with one another or in a sequence other than the exemplary sequence described herein. For example, steps 100, 110 can be carried out at least partially overlapping in time or simultaneously with one another or in a different sequence (110, 100). In further preferred embodiments, this also applies accordingly to the further preferred embodiments described below, for example.

In further preferred embodiments, second wafer 220 is an unstructured wafer (in particular at the beginning, i.e. prior to the applying 120 of sealing material DM).

FIG. 1 schematically shows a top view of first wafer 210, which has a plurality of functional elements FE (in this example nine functional elements). In further preferred embodiments, it is provided that some, preferably all, of the functional elements FE are surface acoustic wave (SAW) functional elements FE, wherein in particular the functional elements FE are arranged on a first surface 210a of first wafer 210 or are at least partially integrated into first surface 210a.

A surface acoustic wave, abbreviated with SAW, is a structure-borne sound wave that propagates in a planar manner on a surface. SAW function elements FE or SAW sensors, which can have one or more SAW function elements FE, utilize e.g. the dependence of the surface wave velocity on mechanical stress (deformation) and/or mass application (e.g. deposits on the surface) and/or temperature (temperature coefficient of the sound velocity). In particular where locations to be measured are hardly accessible for certain reasons, the use of SAW functional elements FE or SAW sensors may be suitable.

A particular challenge in the manufacture and use of SAW functional elements FE or SAW sensors comprising one or more SAW functional elements FE is the protection of the surface of the SAW functional element(s) FE against contamination.

In this respect, the principle according to preferred embodiments advantageously enables a process-safe and, in particular, economical manufacture of SAW functional elements FE and/or SAW sensors, as well as an efficient protection against contamination in particular of the surface of SAW functional element(s) FE during the manufacturing process and subsequent use.

In further preferred embodiments, it is provided that after the placing 130 (FIG. 7A), at least one frame structure RS (FIG. 2) surrounds at least one functional element FE (FIG. 1) of the plurality of functional elements. This can be seen, for example, from the schematic superposition of the two wafers 210, 220 according to FIG. 3, in which a first frame structure RS1 surrounds a first functional element FE1, a second frame structure RS2 surrounds a second functional element FE2, etc., cf. ninth functional element FE9 surrounded by ninth frame structure RS9. With the above-described approach according to preferred embodiments, an interior I (cf. the side view of FIG. 6A) can be defined in the region of a respective functional element FE, which interior includes the at least one functional element FE and can be, preferably hermetically, sealed from the environment by the two wafers 210, 220 and by frame structure RS. In other words, in further preferred embodiments, corresponding regions of first wafer 210 (which are surrounded, for example, by frame structure RS, RS1, . . . ) may form a bottom wall delimitating interior I (FIG. 6A), corresponding regions of second wafer 220 may form a top wall delimitating interior I, and frame structure RS, RS1, RS2, . . . may form at least one side wall which can be coupled in a preferably hermetically sealed manner to the bottom wall and the top wall. This enables an efficient, preferably hermetic, encapsulation of the respective interior I, which in particular protects the functional element(s) FE located therein from environmental influences during (further) fabrication or processing and during subsequent use in a target system (e.g. SAW sensor for determining a quantity characterizing a torque).

In further preferred embodiments, it is provided that after the placing 130 (FIG. 7A), a plurality of frame structures RS each surround at least a predeterminable first number of functional elements FE. Thus, one or more functional elements FE can be surrounded at least laterally by frame structure(s) RS.

In further preferred embodiments, it is provided that after the applying (FIG. 7A), a plurality of frame structures RS each surround exactly a predeterminable second number of functional elements FE, wherein in particular the second number is less than or equal to four, wherein in particular the second number is exactly one. This condition is shown by way of example in FIGS. 3 and 6A.

In further preferred embodiments, however, as already mentioned above, also a plurality of functional elements FE can be arranged in a common interior I and can be surrounded by a (single) frame structure RS (not shown). In this case, the plurality of functional elements FE quasi share the common sealed interior I.

Accordingly, in further preferred embodiments, it may be provided that the one or more frame structures RS, RS1, RS2, . . . are applied to second wafer 220 depending on an arrangement of functional elements FE on first wafer 210. In further preferred embodiments, this may relate to at least one of the present aspects: a) a spacing of functional elements FE, b) an angular orientation of the functional elements.

In further preferred embodiments, it is provided that more than 50 percent of the plurality of frame structures RS (FIG. 2) each surround exactly the (respective) second number of functional elements FE, wherein in particular more than 90 percent of the plurality of frame structures each surround exactly the second number of functional elements.

In further preferred embodiments, it is possible that a first number of frame structures is provided on second wafer 220, each of which is arranged and configured to be associated with or to surround a first predeterminable number of functional elements FE (e.g., exactly one functional element FE each), wherein a second number of frame structures is provided on (the same) second wafer 220, each of which is arranged and configured to be associated with or to surround a second predeterminable number of functional elements FE (e.g., two functional elements FE each). In this way, to remain with the above example, a wafer assembly 200 can be obtained in which a first number of individually, in particular hermetically, sealed functional elements FE and a second number of groups of, in particular hermetically, sealed functional elements (two each) are present.

In further preferred embodiments, it is provided that at least some of frame structures RS, preferably all of frame structures RS, have a height H1 (FIG. 4B) between 1.0 micrometer (μm) and 30 μm, in particular between 2.5 μm and 20 μm, further in particular between 5 μm and 15 μm, and preferably about 10 μm. Thus, interior I to be sealed (FIG. 6A) has a corresponding, in particular sufficient, height to accommodate any SAW functional elements FE or individual SAW structures thereof protruding from a surface plane of first wafer 210, without these touching second wafer 220, for example after joining 140.

In further preferred embodiments, it is provided that the applying 120 of sealing material DM in the form of the plurality of frame structures RS comprises: applying the plurality of frame structures RS in a matrix-shaped arrangement having a plurality of rows and a plurality of columns, cf. e.g. FIG. 2.

In further preferred embodiments, it is provided that the applying 120 of sealing material DM in the form of the plurality of frame structures RS comprises: applying the plurality of frame structures RS such that at least a first spacing d1 (FIG. 2) of adjacent frame structures RS on first surface 220a of second wafer 220, which is viewed in particular along a first (horizontal in FIG. 2) coordinate axis x1, corresponds to a corresponding second spacing d2 (FIG. 1) of adjacent functional elements FE on first wafer 210, wherein in particular the applying 120 of sealing material DM in the form of the plurality of frame structures RS comprises: applying the plurality of frame structures RS such that first distance d1 of adjacent frame structures RS on first surface 220a of second wafer 220, which is viewed in particular along first coordinate axis x1, corresponds to corresponding second distance d2 of adjacent functional elements FE on first wafer 210, and that a third distance d3 (FIG. 2) of adjacent frame structures RS on first surface 220a of second wafer 220, which is viewed in particular along a second coordinate axis x2 perpendicular to the first coordinate axis x1 (vertical in FIG. 2), corresponds to a corresponding fourth distance d4 (FIG. 1) of adjacent functional elements FE on first wafer 210.

In further preferred embodiments, in which, for example, also a plurality of functional elements FE may be surrounded by a common frame structure RS (not shown), the same may apply to the respective spacing.

In other preferred embodiments, distances d1, d3 are in particular not equal. This may allow to provide space for electrical contacting in some regions, in particular outside of frame structures RS. The same or similar applies to distances d2, d4 in further preferred embodiments. This can be derived, for example, from FIG. 11 described further below.

In further preferred embodiments, it is provided that at least some of frame structures RS (FIG. 2), preferably all of frame structures RS, have a substantially polygonal basic shape, in particular rectangular (or also rounded rectangular shape) or square shape.

In further preferred embodiments, it is provided that the applying 120 of sealing material DM is performed using a screen printing method. In this way, sealing material DM can be applied to second wafer 220 (FIG. 2) particularly efficiently, e.g. with the aforementioned frame structure RS.

In further preferred embodiments, it is provided that a glass solder is used as the sealing material DM. The glass solder can preferably be used for efficiently creating a sealed, in particular a cohesive, connection with the respective surfaces 210a, 220a of the respective wafers 210, 220. At the same time, the glass solder as the sealing material DM can define a clearance height of interior I (FIG. 6A) that ensures that SAW structures and/or other structures of functional elements FE are sufficiently spaced from second wafer 220 or its first surface 220a facing first wafer 210, in order to ensure proper functioning of the SAW structures and/or other structures of functional elements FE in the, preferably hermetically, sealed state.

In further preferred embodiments, it is provided that the method further comprises, cf. also the flow chart of FIG. 7B: performing 125 a heat treatment on second wafer 220 (FIG. 2) on which sealing material DM is applied in the form of the plurality of frame structures RS, RS1, RS2, . . . , wherein in particular the heat treatment has a predeterminable temperature profile. In further preferred embodiments, performing 125 the heat treatment may be performed after step 120 (FIG. 7A) of applying and/or before step 130 of placing. In further preferred embodiments, heat treatment 125 may effect a so-called “pre-vitrification”, in which, for example, particles of sealing material DM, in particular of the glass solder, fuse together and preferably form a homogeneous, flowable and preferably at least substantially bubble-free mass. In further preferred embodiments, for example, a muffle furnace may be used to perform heat treatment 125 or at least parts of heat treatment 125.

In further preferred embodiments, it is provided that performing 125 (FIG. 7B) the heat treatment comprises: heating 125a second wafer 220 during a first period to a predeterminable first temperature, wherein in particular the first period is between 20 minutes and 120 minutes, preferably 60 minutes, wherein in particular the first temperature is between 420 and 690 degrees Celsius, preferably between 520 and 600 degrees Celsius, and further preferably about 560 degrees Celsius.

In further preferred embodiments, it is provided that performing 125 the heat treatment comprises: maintaining 125b a predeterminable second temperature for a second period (which preferably directly follows the first period, cf. the phase of heating 125a), wherein in particular the predeterminable second temperature corresponds at least approximately to the first temperature, wherein in particular the second period is between 10 minutes and 90 minutes, further in particular between approximately 20 minutes and approximately 60 minutes, further preferably about 40 minutes.

In further preferred embodiments, it is provided that performing 125 the heat treatment comprises: cooling 125c, in particular to room temperature, during a third period (which preferably directly follows the second period, cf. the phase of maintaining 125b), wherein in particular the third period is between 6 hours to 24 hours, further in particular between 12 hours and 20 hours, further preferably between 15 hours and 18 hours.

In further preferred embodiments, it is provided that the method further comprises, cf. FIG. 7B: removing 126 material from first surface 220a of second wafer 220, cf. FIG. 4B, down to a predeterminable first depth T1, which is preferably less than 80 percent of a thickness D2 of second wafer 220, in particular less than 60 percent of thickness D2 of second wafer 220. This results in the trenches TR shown schematically in FIG. 4B, e.g. between adjacent frame structures RS, which simplify subsequent dicing, cf. FIGS. 6C, 6D.

In further preferred embodiments, it is provided that the removing 126 (FIG. 7B) is performed after performing 125 the heat treatment.

In further preferred embodiments, it is provided that removing 126 of material is performed between mutually adjacent frame structures RS, cf. FIG. 4B.

In further preferred embodiments, it is provided that removing 126 of material comprises performing one or more saw cuts, e.g. along the saw lines indicated in FIG. 4A by means of undesignated, dashed straight lines (i.e. in particular also along several e.g. mutually orthogonal coordinate directions within the plane of second wafer 220). For example, in further preferred embodiments, trenches TR according to FIG. 4B can be created by means of one saw cut respectively between mutually adjacent frame structures. Further preferred embodiments provide for multiple, e.g. two, saw cuts between mutually adjacent frame structures and are described further below with reference to FIGS. 9A, 9B, 9C.

In further preferred embodiments, it is provided that first depth T1 (FIG. 4B) is between 20 μm and 150 μm, in particular between 20 μm and 100 μm.

In contrast, a thickness D2 of the second wafer may be, for example, between 200 μm and 400 μm.

In further preferred embodiments, a thickness D1 of first wafer 210 (FIG. 5) may be, for example, between 200 μm and 400 μm.

In further preferred embodiments, a step of cleaning of second wafer 200 may be performed after the removing, in particular sawing, 126 (FIG. 7B), and in particular before placing 130 or joining 140. In further preferred embodiments, the cleaning may comprise, for example, vacuuming of sawing dust and/or mechanical cleaning such as wiping. In further preferred embodiments, the cleaning may be integrated in step 126, for example.

In further preferred embodiments, it is provided that the joining 140 (FIG. 7A) comprises: pressing first wafer 210 (FIG. 5) to second wafer 220 (FIG. 4B) under a predeterminable pressure and/or a predeterminable temperature, wherein the predeterminable pressure is between about 200 Pascal (Pa) and about 12000 Pa, in particular between 500 Pa and 6000 Pa, wherein in particular the predeterminable temperature is between 300 and 700 degrees Celsius. In particular, this advantageously provides a (preferably hermetically) sealed cohesive connection between the components 210a, RS, 220a.

In further preferred embodiments, it is provided that the pressing is carried out for a period of 5 seconds to 10 hours, in particular of 10 seconds to 5 hours, in particular of 1 minute to 1 hour.

In further preferred embodiments, it is provided that the method further comprises, cf. FIG. 7C: removing 150 material from second surface 220b (FIG. 6A) of second wafer 220, in particular by grinding and/or milling, wherein in particular the removing 150 is performed such that several regions of the second wafer are separated (diced) from each other. For this purpose, FIG. 6B schematically shows a partitioning of second wafer 220 into two horizontal regions 220′ (shown hatched), 220″ in FIG. 6B, wherein, for example, the hatched region 220′ is removed in the step of removing 150 (FIG. 7C) by grinding and/or milling. In FIG. 6b, the vertical thickness of hatched area 220′ to be removed can preferably be selected such that hatched area 220′ to be removed touches or intersects trenches TR previously created in step 126, whereby individual regions B1, B2, B3 of second wafer 220 are defined or separated from each other, cf. also the reference signs TR′ of FIG. 6C. After removing 150, these regions B1, B2, B3 are held to first wafer 210 or its surface 210a in particular solely via frame structures RS. As before, in the state shown in FIG. 6C, simple handling of arrangement 200 at wafer level is possible, since first wafer 210 quasi forms a “holder” for regions B1, B2, B3 diced by step 150.

In further preferred embodiments, it is provided that the method, cf. FIG. 7C, further comprises: testing 160, in particular preferably electrically characterizing, of individual or multiple functional elements, in particular at wafer level. Electrical characterizing may comprise, for example, electrically contacting electrical contacts (not shown in FIG. 1, for details see below as regards FIG. 8), e.g. also arranged on first surface 210a (FIG. 1) of first wafer 210, and performing electrical measurements on these contacts. This enables, for example, to determine whether individual functional elements, which are already sealed, in particular hermetically sealed, in the state shown in FIG. 6C, are electrically operating correctly. Also here, handling at wafer level, i.e. handling of the monolithic wafer assembly 200, is very advantageous compared with the electrical characterization of functional elements that have already been completely separated, for example.

In further preferred embodiments, it is provided that the method further comprises, see FIG. 7C: dicing (separating) 170 several of the functional elements, in particular by sawing, e.g. along the lines L1, L2 schematically indicated in FIG. 6D. Preferably, further saw cuts can also be made in further planes of wafer assembly 200 at least substantially parallel to the drawing plane of FIG. 6D, in order to dice the functional elements.

FIG. 6E shows an example of a side view of the diced functional elements FE1, FE2, FE3 obtained in this way.

In further preferred embodiments it is provided that the method further comprises, cf. FIG. 7C: further processing 180 of at least one diced functional element FE1, FE2, FE3, in particular installing the at least one diced functional element FE1, FE2, FE3 in a target system (not shown), e.g. soldering and/or bonding onto e.g. a) a mechanical shaft, b) a carrier. There, sealed functional element FE1 can be used, for example, to determine a quantity (e.g. torsion or other deformation of the shaft) which characterizes a torque transmitted by the shaft.

In further preferred embodiments, it is provided that first wafer 210 (FIG. 1) and/or second wafer 220 (FIG. 2) is a quartz wafer. In further preferred embodiments, it is provided that first wafer 210 and/or second wafer 220 comprises at least one of the following materials: lithium niobate (LiNbO₃) and/or lithium tantalate (LiTaO₃).

Further preferred embodiments relate to a wafer assembly 200 (FIG. 6A) comprising a first wafer 210 having a plurality of functional elements FE and a second wafer 220, obtained by the method according to the embodiments.

Further preferred embodiments relate to a sealed functional element FE1 (FIG. 6E) obtained by the method according to the embodiments.

Further preferred embodiments, cf. FIG. 6E, refer to a preferably hermetically sealed functional element FE1 comprising a first substrate S1 (e.g. portion of first wafer 210 according to FIG. 1), on which functional element FE is located, at least one second substrate S2 (e.g. portion of second wafer 220 according to FIG. 2), and at least one frame structure RS surrounding functional element FE (FIG. 6E), wherein first substrate S1 is connected, in particular cohesively connected, to second substrate S2 by frame structure RS, wherein an, in particular hermetically, sealed interior I is defined between first substrate S1 and second substrate S2 and frame structure RS. Within interior I, functional element FE is already protected from environmental influences during parts of the manufacturing process as well as during installation in a target system and during subsequent use in the target system.

Further preferred embodiments relate to a use of at least one sealed functional element FE1 (FIG. 6E) according to the embodiments for determining a quantity which characterizes a torque. FIG. 8 schematically shows a perspective view of a sealed functional element FE1′ according to further preferred embodiments. First substrate S1 (e.g. portion of first wafer 210, FIG. 1), second substrate S2 (e.g. portion of second wafer 220, FIG. 1), which in the present case quasi forms a “protective cover” for functional element FE′ located on first surface 210a of first wafer 210, and frame structure RS, which—together with substrates S1, S2—defines the sealed interior I, can be seen. Optionally, one or more electrical contacts K1, K2, e.g. for electrical contacting of functional element FE′, can preferably also be provided on first surface 210a of first wafer 210. Electrical contacts K1, K2 can be created, e.g. by means of manufacturing techniques known per se, so that they are already present for step 100 (FIG. 7A) of providing the electrical contacts, for example.

In further preferred embodiments, in step 126 (FIG. 7B) of removing material from first surface 220a of second wafer 220 (FIG. 4B), the material may be removed such that contacts K1, K2, if any, disposed on first wafer 210 or its first surface 210a are not covered with material of second wafer 220 by the placing 130 (FIG. 7A), but rather the trenches TR (FIG. 6B) face the contacts K1, K2 (FIG. 8), for example. Contacts K1, K2 can then be exposed by the removing 150 (FIG. 7C), for example.

FIG. 9A schematically shows a side view of a second wafer 2200 according to further preferred embodiments. Similar to second wafer 220 according to FIG. 4B, second wafer 2200 of FIG. 9A also has frame structures, of which two mutually adjacent frame structures RSa, RSb are shown here as an example. In contrast to the configuration 220 according to FIG. 4B, two trenches TRa, TRb are arranged between mutually adjacent frame structures RSa, RSb of FIG. 9A, which in turn can be created, for example, by means of saw cuts, in particular parallel to each other.

FIG. 9B shows second wafer 2200 of FIG. 9A after placing on and joining with a first wafer 2100 having a configuration similar to first wafer 210 according to FIG. 5, wherein as an example two functional elements FE″a, FE″b of first wafer 2100 are shown in FIG. 9B. Functional elements FE″a, FE″b of first wafer 2100 each have, for example, an electrical contacting similar to the configuration FE′ according to FIG. 8, wherein in FIG. 9B only a second contact K2′ of functional element FE″a and a first contact K1′ of functional element FE″b adjacent thereto are shown. The same applies to any further electrical contacts of functional elements FE″a, FE″b which are not shown in FIG. 9B for the sake of clarity.

The two trenches TRa, TRb ensure that after removing (cf. step 150 according to FIG. 7C) of material from second surface 2200b of second wafer 2200, in particular by grinding and/or milling, region 2202 of second wafer 2200 is exposed so that electrical contacts K1′, K2′ in a contact area KB are accessible from outside (in FIG. 9B, e.g., from above), which allows, for example, an electrical characterization or testing 160 (FIG. 7C) of functional elements FE″a, FE″b, cf. arrows EC of FIG. 9C. This can advantageously be done on wafer level, because functional elements FE″a, FE″b are not yet diced, but still connected via first wafer 2100, see FIG. 9C. A subsequent dicing 170 (FIG. 7C), e.g. by sawing along line L1′ of FIG. 9C (for example after the optional testing EC at wafer level), finally results in a plurality of diced functional elements.

FIG. 9D schematically shows a top view of a functional element according to further preferred embodiments. The freely accessible contacts K1′, K2′ arranged on the right and left of frame structure RS on the surface of first wafer 2100, as well as an unspecified SAW structure in the hermetically sealed interior I are visible.

FIG. 10 schematically shows a top view of a portion of a wafer assembly 2000 according to further preferred embodiments. Wafer assembly 2000 has a plurality of not individually designated hermetically sealed functional elements. In the state shown in FIG. 10, electrical contacts K1, K2 (FIG. 8) of each functional element are already exposed, so that electrical characterization and/or testing of individual, preferably all, functional elements can advantageously still be performed at wafer level, which simplifies handling. After testing, the functional elements can be diced (cf. e.g. step 170 of FIG. 7C), which can be done, for example, by sawing along saw lines L1″, L2 (vertical) and L1′″, L2 (horizontal, only two lines shown as an example) schematically indicated in FIG. 10.

Similar to FIG. 3, FIG. 11 schematically shows a top view of functional elements FE′1, FE′2 of a virtual superposition of a first wafer and a second wafer according to further preferred embodiments. It can be seen that in the present case two adjacent functional elements FE′1, FE′2 are surrounded by a common frame structure RS1 made of sealing material DM. In this way, the two functional elements FE′1, FE′2 can be arranged together (and, if necessary, later diced) in the preferably hermetically sealed interior I between corresponding regions of first and second wafers. Electrical contacts are not shown in FIG. 11 for the sake of clarity, but in further preferred embodiments they can be designed, for example, analogously to FIG. 8 or 9D.

1. A method for manufacturing a plurality of sealed functional elements, the method comprising:
providing a first wafer including the plurality of functional elements;
providing a second wafer;
applying a sealing material in a form of a plurality of frame structures on a first surface of the second wafer;
placing one of the first wafer and the second wafer on another one of the second wafer and the first wafer; and
joining the first wafer with the second wafer, wherein the method further includes
removing, prior to the placing, material from the first surface of the second wafer between mutually adjacent frame structures down to a first depth that is less than 80 percent of a thickness of the second wafer.

2. The method according to claim 1, wherein some of the sealed functional elements are surface acoustic wave functional elements.

3. The method according to claim 1, wherein after the placing, at least one frame structure surrounds at least one functional element of the plurality of sealed functional elements.

4. The method according to claim 1, wherein after the placing a plurality of frame structures each surround at least a first number of the plurality of sealed functional elements.

5. The method according to claim 1, wherein after the placing, a plurality of frame structures each surround exactly a second number of the plurality of sealed functional elements.

6. The method according to claim 5, wherein more than 50 percent of the plurality of frame structures each surround exactly the second number of the plurality of sealed functional elements.

7. The method according to claim 1, wherein at least some of the frame structures, have a height between 1.0 micrometer and 30 μm.

8. The method according to claim 1, wherein the applying of the sealing material in the form of the plurality of frame structures comprises: applying the plurality of frame structures in a matrix-shaped arrangement having a plurality of rows and a plurality of columns.

9. The method according to claim 1 wherein the applying of the sealing material in the form of the plurality of frame structures comprises: applying the plurality of frame structures such that at least a first distance of adjacent frame structures on the first surface of the second wafer, viewed along a first coordinate axis, corresponds to a corresponding second distance of adjacent functional elements on the first wafer.

10. The method according to claim 1, wherein at least some of the frame structures have a substantially polygonal basic shape.

11. The method according to claim 1, wherein the applying of the sealing material is performed using a screen printing method.

12. The method according to claim 1, wherein a glass solder is used as the sealing material.

13. The method according to claim 1, further comprising:
performing a heat treatment on the second wafer on which the sealing material is applied, in a form of the plurality of frame structures.

14. The method according to claim 13, wherein the performing of the heat treatment comprises: heating the second wafer during a first period to a first temperature, wherein the first period is between 20 minutes and 120 minutes.

15. The method according to claim 14, wherein the performing of the heat treatment comprises: maintaining a second temperature for a second period, the second temperature being at least approximately equal to said first temperature, and wherein said second period is between 10 minutes and 90 minutes.

16. The method according to claim 14, wherein the performing of the heat treatment comprises: cooling during a third period, the third period being between 6 hours to 24 hours.

17. The method according to claim 1, wherein a cleaning of the second wafer is performed at least one of during and after the removing.

18. The method according to claim 1, wherein the removing is performed after performing of the heat treatment.

19. The method according to claim 1, wherein the first depth is less than 60 percent of a thickness of the second wafer.

20. The method according to claim 1, wherein removing of material comprises performing of saw cuts.

21. The method according to claim 1, wherein the first depth is between 20 μm and 150 μm.

22. The method according to claim 1, wherein the joining comprises: pressing the first wafer to the second wafer under at least one of a pressure and a temperature, the pressure being between about 200 Pascal and about 12000 Pa and temperature between 300 and 700 degrees Celsius.

23. The method according to claim 22, wherein the pressing is performed for a period of 5 seconds to 10 hours.

24. The method according to claim 1, further comprising: removing material from the second surface of the second wafer, the removing being performed such that a plurality of regions of the second wafer are separated from each other.

25. The method according to claim 1, further comprising: testing of individual or multiple functional elements.

26. The method according to claim 1, further comprising: separating a plurality of functional elements.

27. The method according to claim 26, further comprising: further processing of at least one separated functional element.

28. The method according to claim 1, wherein at least one of the first wafer and the second wafer is a quartz wafer or comprises at least one of lithium niobate, and lithium tantalate.

29. A wafer assembly comprising a first wafer having a plurality of functional elements and a second wafer, obtained by the method according to claim 1.

30. A sealed functional element obtained by the method according to claim 1.

31. A method, comprising:
determining a quantity which characterizes a torque using the sealed functional element according to claim 30.
